(19) United States
(12) Patent Application Publication
(10) Pub. No.: US 2008/0139014 A1
(43) Pub. Date: Jun. 12, 2008

(54) Interconnect assemblies, and methods of forming interconnects

(75) Inventor: Barry W. Eppler, Berthoud, CO (US)

Correspondence Address: VERIGY, LTD., IP LEGAL DEPARTMENT, 10100 N. TANTAU AVENUE, CUPERTINO, CA, 95014-2540, US

(73) Assignee: Verigy (Singapore) Pte. Ltd., Singapore (SG)

(21) Appl. No.: 11/636,244

(22) Filed: Dec. 8, 2006

(51) Int. Cl. H01R 12/22; H05K 3/36

(52) U.S. Cl. 439/66; 29/830

(57) ABSTRACT

There are disclosed interconnect assemblies. In an embodiment, an interconnect assembly may include a rigid printed circuit assembly having a substrate, conductive contact pads disposed on the substrate, the conductive contact pads configured for selective engagement with the conductive contact bumps, bumped flex circuit assemblies having support plates and conductive contact bumps; and a hard stop assembly extending between from the substrate, wherein the hard stop assembly restricts non-uniform motion of the substrate toward the first and second support plates. Methods of forming interconnects are provided. In an embodiment, a method may include positioning hard stop assemblies extending from first and second support plates in contact with a rigid printed circuit assembly; and positioning first and second pluralities of conductive contact bumps in electrical contact with first and second pluralities of conductive contact pads, respectively. Other embodiments are also disclosed.

### BACKGROUND

Effective high-density electrical interconnect is essential to the design and operation of many electrical measurement products, including automatic test equipment. Some electrical measurement products may use a bumped flex circuit interconnect technology. FIGS. 1A-3 are illustrative of an example of one such bumped interconnect device. A manufacturer of these types of interconnect devices is Xandex, Inc. of Petaluma, Calif.

Many existing designs of bumped flex circuit interconnect devices have reliability problems. Open circuits and circuits with unacceptably high resistance are some of these problems. Such problems may be caused because there is no suitable mechanical reference between contact pads on the rigid printed circuit assembly and corresponding bumps on the flexible printed circuit assembly.

### SUMMARY OF THE INVENTION

In an embodiment, there is provided an interconnect assembly, comprising a rigid printed circuit assembly having a substrate with first and second sides in opposition to one another, first and second pluralities of conductive contact pads disposed on the first and second sides of the substrate, respectively, the first and second pluralities of conductive contact pads; first and second bumped flex circuit assemblies having first and second support plates, respectively, said first and second pluralities of conductive contact bumps extending inwardly toward one another from the first and second support plates, respectively, and the first and second pluralities of conductive contact bumps configured for selective engagement with the first and second pluralities of conductive contact pads; and a hard stop assembly configured to extend between the first and second support plates and the first and second sides of the substrate, respectively, wherein the hard stop assembly restricts non-uniform motion of the substrate toward first and second support plates.

In another embodiment, there is provided a method of forming an interconnect, the method comprising positioning hard stop assemblies extending from first and second support plates of first and second bumped flex circuit assemblies, respectively, in contact with a rigid printed circuit assembly; and positioning first and second pluralities of conductive contact bumps of the first and second bumped flex circuit assemblies in electrical contact with first and second pluralities of conductive contact pads of the rigid printed circuit assembly, respectively.

In still another embodiment, there is provided a method of forming an interconnect, the method comprising positioning hard stop assemblies extending from a rigid printed circuit assembly in contact with first and second support plates of first and second bumped flex circuit assemblies, respectively; and positioning first and second pluralities of conductive contact bumps of the first and second bumped flex circuit assemblies in electrical contact with first and second pluralities of conductive contact pads of the rigid printed circuit assembly, respectively.

Other embodiments are also disclosed.

### BRIEF DESCRIPTION OF THE DRAWINGS

Illustrative embodiments of the invention are illustrated in the drawings, in which:

FIGS. 1A and 1B illustrate schematic elevational views of an exemplary bumped interconnect device with a pair of bumped flex circuit assemblies and a rigid printed circuit assembly configured for electrical connection with one another;

FIGS. 2A and 2B illustrate plan views of a portion of the rigid printed circuit assembly shown in FIGS. 1A and 1B, which illustrates conductive contact pads disposed on the surface of the rigid printed circuit assembly;

FIG. 3 schematically illustrates a cross-sectional profile of a rigid printed circuit assembly held by a bumped interconnect device without a hard stop assembly in which there is deflection of the somewhat elastic substrate;

FIGS. 4A and 4B illustrate plan views of a portion of a novel rigid printed circuit assembly having a substrate and a hard stop assembly;

FIGS. 5A and 5B illustrate perspective views of a portion of the novel rigid printed circuit assembly shown in FIGS. 4A and 4B;

FIG. 6 illustrates a side elevational view of the novel rigid printed circuit assembly, which is shown in FIGS. 4A, 4B, 5A and 5B, clamped together with support plates of the bumped flex circuit assemblies;

FIG. 7 illustrates a side elevational view of the novel rigid printed circuit assembly separate from the support plates of the bumped flex circuit assemblies;

FIG. 8 illustrates a side elevational view of another novel rigid printed circuit assembly with a substrate having a greater height than that of the rigid printed circuit assembly shown in FIG. 7; and

FIGS. 9 and 10 illustrate exemplary methods of forming interconnects.

### DETAILED DESCRIPTION OF AN EMBODIMENT

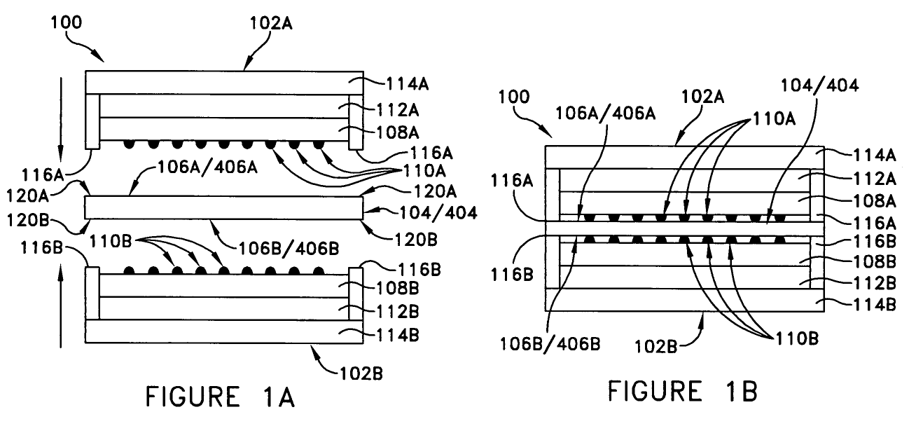

Looking at FIGS. 1A and 1B, there is shown one example of an interconnect assembly 100 having at least one bumped flex circuit assembly 102A/102B for electrical connection with a rigid printed circuit assembly 104. As shown, there may be provided a pair of bumped flex circuit assemblies 102A and 102B for electrical connection with two outer surfaces 106A and 106B of rigid printed circuit assembly 104, respectively.

Generally, a bumped flex circuit 108A/108B may include a plurality of conductive contact bumps 110A/110B disposed on one side of each bumped flex circuit 102A/102B. An elastomer pad 112A/112B and a support plate 114A/114B may be disposed on the other side of each bumped flex circuit assembly 102A/102B. Rigid hard stops 116A/116B may be disposed on bumped flex circuit 102A/102B in opposition to other corresponding hard stops 116A/116B.

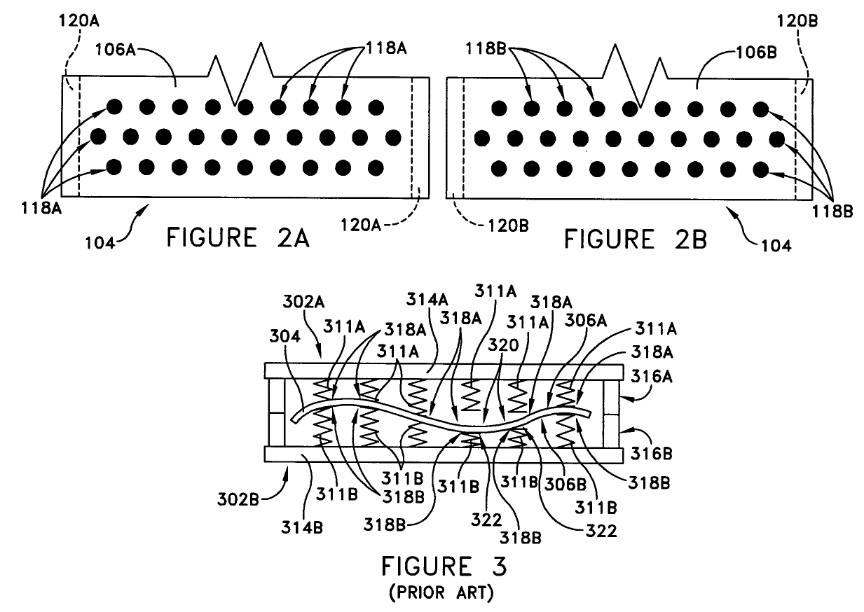

As best shown in FIGS. 2A and 2B, rigid printed circuit assembly 104 may include a plurality of conductive contact pads 118A (FIG. 2A) disposed on outer surface 106A (FIG. 2A) and may also include a plurality of conductive contact pads 118B (FIG. 2B) disposed on outer surface 106B (FIG. 2B). Rigid printed circuit assembly 104 may also include contact zones 120A disposed on outer surface 106A (FIG. 2A) and contact zones 120B disposed on outer surface 106B (FIG. 2B). Rigid hard stops 116A/116B (FIGS. 1A and 1B) may be configured to interface with areas of the rigid printed circuit assembly 104, such as contact zones 120A/120B.

In an embodiment, interconnect assembly 100 may include rigid printed circuit assembly 104 having a substrate with first and second sides 106A/106B in opposition to one another. First and second pluralities of conductive contact pads 118A/118B may be disposed on the first and second sides 106A/106B of the substrate, respectively. First and second bumped flex circuit assemblies 102A/102B may have first and second support plates 114A/114B, respectively. First and second pluralities of conductive contact bumps 110A/110B extending inwardly toward one another from the first and second support plates 114A/114B, respectively. First and second pluralities of conductive contact bumps 110A/110B may be configured for selective engagement with first and second pluralities of conductive contact pads 118A/118B. A hard stop assembly may include, for example, rigid hard stops 116A/116B and may be configured to extend between first and second support plates 114A/114B and first and second sides 106A/106B of the substrate, respectively. Hard stop assembly 116A/116B may restrict non-uniform motion of the substrate toward first and second support plates 114A/114B.

In one embodiment, interconnect assembly 100 may include the hard stop assembly with first and second pairs of rigid supports 116A/116B extending from first and second support plates 114A/114B, respectively. First and second pairs of rigid supports 116A/116B may extend a maximum height in a direction perpendicular to a plane in parallel with first and second support plates 114A/114B, respectively. As such, the maximum height may be selected to allow contact and provide a substantially uniform pressure between each of the first and second pluralities of conductive contact bumps 110A/110B and the first and second pluralities of conductive contact pads 118A/118B, respectively. The maximum height of each of the first and second pairs of rigid supports 116A/116B may be uniform along an entire length thereof. In an embodiment, the maximum height of the first pair of rigid supports 116A may be equal to the maximum height of the second pair of rigid supports 116B.

Referring to FIG. 3, there is shown a schematic diagram with spring portions 311A and spring portions 311B representative of conductive contact bumps 110A and conductive contact bumps 111B, bumped flex circuit 108A and bumped flex circuit 108B, and elastomer pad 112A and elastomer pad 112B, respectively. As shown, distortion of rigid printed circuit assembly 304 may occur when bumped flex circuit assemblies 302A and 302B close together for contact.

Distortion of rigid printed circuit assembly 304 may cause one or more of low contact areas and non-contacting areas between conductive contact bumps and conductive contact pads 318A/318B. Such low contact or no contact areas may cause one or more open circuits. These areas are illustrated as portions 320 between spring model and conductive contact pads 318A/318B.

Insufficient compression between conductive contact bumps may cause unacceptably high resistance. Excessive compression may damage softer portions of these components. Portions 322 of spring model are illustrative of excessive contact stress between conductive contact bumps and conductive contact pads 318A/310B.

In general, electrical interconnects with high quality and high reliability produce relatively uniform contact stresses between various components of electrical interconnect 100 (FIG. 1). The somewhat elastic substrate of rigid printed circuit assembly 304 may allow deflection, as shown in cross-sectional profile 324 (FIG. 3), when flexible printed circuit assemblies 302A and 302B clamp together on rigid printed circuit assembly 304, and conductive contact bumps 310A/310B and conductive contact pads 318A/318B meet with one another.

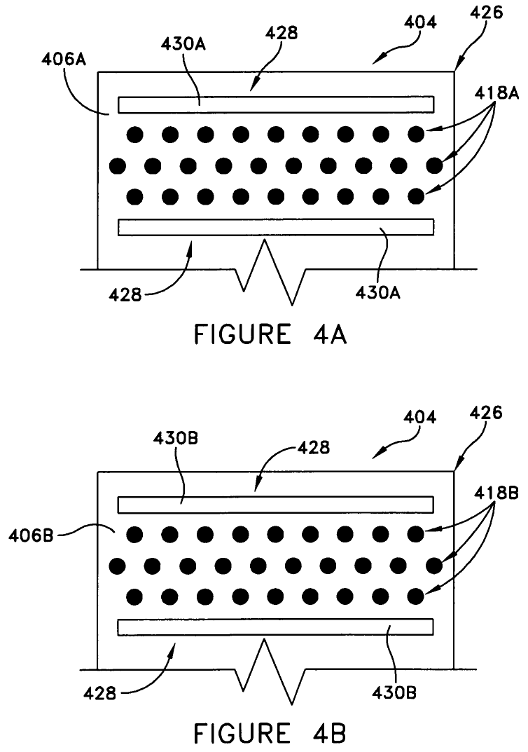

Referring now to FIGS. 4A, 4B, 5A, 5B, 6 and 7, and in an embodiment, there is shown an exemplary embodiment of a novel rigid printed circuit assembly 404, which is configured for replacing rigid printed circuit assembly 106 in interconnect assembly 100 (FIG. 1).

In FIGS. 4A and 4B there is shown a portion of a novel rigid printed circuit assembly 404 having a first side 406A (FIG. 4A) and a second side 406B (FIG. 4B). Conductive contact pads 418A (FIG. 4A) and 418B (FIG. 4B) extend from substrate 426. A hard stop assembly 428 is provided to prevent distortion of substrate 426. Hard stop assembly 428 may include, but is not limited to, a pair of rigid supports 430A and a pair of rigid supports 430B.

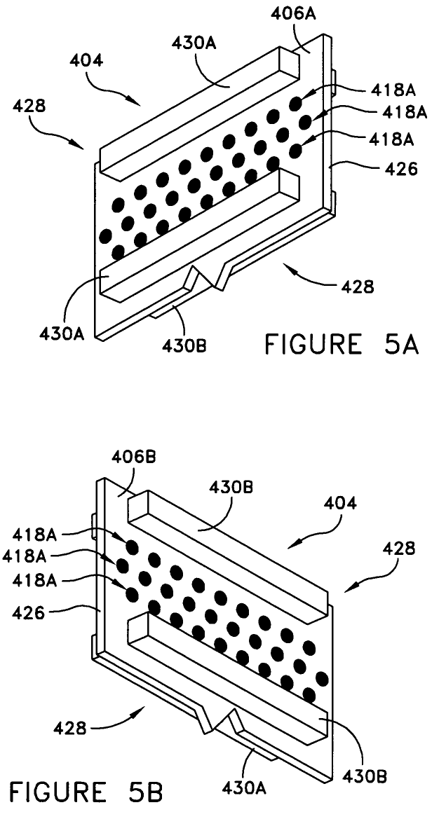

FIGS. 5A and 5B illustrate perspective views of a portion of the novel rigid printed circuit assembly 404. There is shown first side 406A (FIG. 4A) and second side 406B (FIG. 4B).

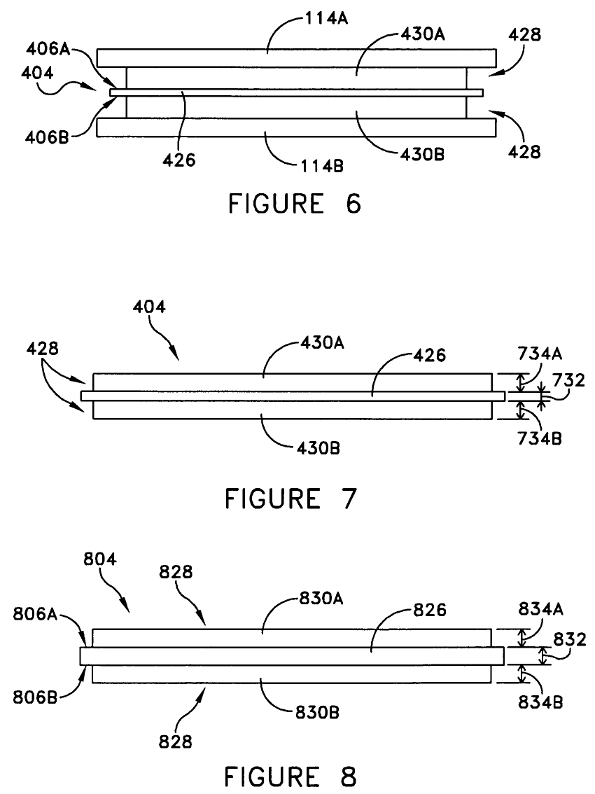

FIG. 6 illustrates a side elevational view of novel rigid printed circuit assembly 404, which is also shown in FIGS. 4A, 4B, 5A and 5B, clamped together with support plates 114A and 114B of bumped flex circuit assemblies 102A and 102B. In an embodiment, supports 430A and 430B are positioned away from conductive contact pads 418A and 418B so as to interface with portions of support plates 114A and 114B that do not include elastomer pad 112A/112B with bumped flex circuit 108A/108B and conductive contact bumps 110A/110B disposed thereon.

In an embodiment, interconnect assembly 100 may include first and second bumped flex circuit assemblies 102A and 102B having first and second support plates 114A and 114B, respectively. First and second pluralities of conductive contact bumps 110A and 110B may extend inwardly toward one another from first and second support plates 114A and 114B, respectively. Rigid printed circuit assembly 404 may include a substrate 426 with first and second sides 406A and 406B in opposition to one another. First and second pluralities of conductive contact pads 418A and 418B may be disposed on first and second sides 406A and 406B of substrate 426, respectively. First and second pluralities of conductive contact pads 418A and 418B may be configured for selective engagement with first and second pluralities of conductive contact bumps 110A and 110B, respectively. Hard stop assembly 428 may extend from first and second sides 406A and 406B of substrate 426. In an embodiment, hard stop assembly 428 restricts motion of first and second support plates 114A and 114B toward substrate 426.

Hard stop assembly 428 may include first and second pairs of rigid supports 430A and 430B. In an embodiment, rigid supports 430A extend from first side 406A of substrate 426 and rigid supports 430B extend from second side 406B of substrate 426.

As best shown in FIG. 7, substrate 426 has a height 732, and first and second pairs of rigid supports 430A and 430B may each extend a maximum height 734A and 734B in a direction perpendicular to a plane parallel with substrate 426. Maximum height 734A and 734B may be selected to allow contact and provide a substantially uniform pressure between each of first and second pluralities of conductive contact bumps 110A and 110B and first and second pluralities of conductive contact pads 418A and 418B, respectively. Maximum height 734A and 734B of each of first and second pairs of rigid supports 430A and 430B may be uniform along the entire length of each one.

FIG. 7 illustrates a side elevational view of novel rigid printed circuit assembly 404. In an embodiment, the maximum height of first pair of rigid supports 430A may be equal to the maximum height of second pair of rigid supports 430B. In one embodiment, rigid printed circuit assembly 404 has a height equal to height 732 of substrate 426 together with maximum height 734A of the first pair of rigid supports 430A together with maximum height 734B of the second pair of rigid supports 430B.

FIG. 8 illustrates a side elevational view of another novel rigid printed circuit assembly 804 with a substrate 826 having a greater height than substrate 426 of the rigid printed circuit assembly 404 shown in FIG. 7.

Referring to both FIGS. 7 and 8, and in an embodiment, replacement of substrate 426 with another substrate 826 having a different height 832 causes a corresponding change in the height of the rigid printed circuit assembly as the maximum height 734A/834A and 734B/834B of the first and second pair of rigid supports 430A/830A and 430B/830B does not change.

In an embodiment, hard stop assembly 428 may include a single pair of rigid supports 430A extending from side 406A of substrate 426. In addition to, or alternatively, hard stop assembly 438 may include a single pair of rigid supports 430B extending from side 406B of substrate 426. Hard stop assembly 428 may include rigid support 430A extending from side 406A of substrate 404. Hard stop assembly 428 may include first and second rigid supports 430A and 430B extending from first and second sides of the substrate 406A and 406B, respectively.

Substrate 426 has a certain amount of stiffness. Hard stop assembly 428 also has a certain amount of stiffness. In an embodiment, the stiffness of hard stop assembly 428 is greater than the stiffness of substrate 426. In another embodiment, substrate 426 has a certain amount of stiffness without hard stop assembly 428, rigid printed circuit assembly 404 has a certain amount of stiffness, and the stiffness of rigid printed circuit assembly 404 is greater than the stiffness of substrate 426 without hard stop assembly 428.

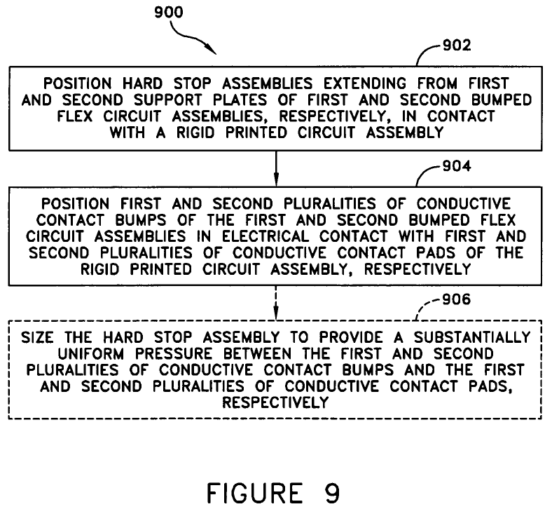

Referring to FIG. 9, there is shown an exemplary method 900 of forming an interconnect. In one embodiment, method 900 may include positioning 902 hard stop assemblies extending from first and second support plates of first and second bumped flex circuit assemblies, respectively, in contact with a rigid printed circuit assembly. Method 900 may further include positioning 904 first and second pluralities of conductive contact bumps of the first and second bumped flex circuit assemblies in electrical contact with first and second pluralities of conductive contact pads of the rigid printed circuit assembly, respectively.

In one embodiment, method 900 of forming an interconnect in may further include sizing 906 the hard stop assembly to provide a substantially uniform pressure between the first and second pluralities of conductive contact bumps and the first and second pluralities of conductive contact pads, respectively.

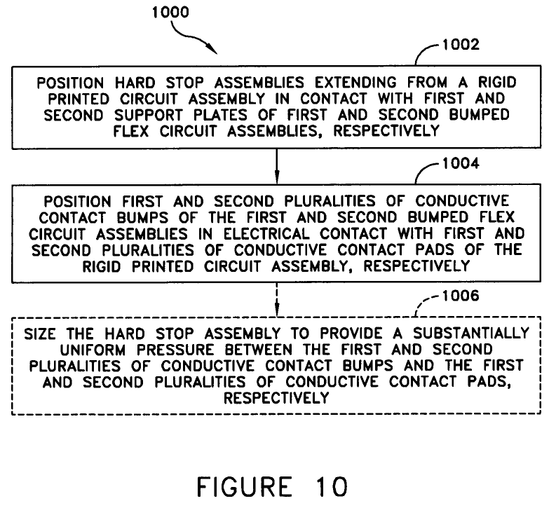

Referring to FIG. 10, there is shown another exemplary method 1000 of forming an interconnect. In one embodiment, method 1000 may include positioning 1002 hard stop assemblies extending from a rigid printed circuit assembly in contact with first and second support plates of first and second bumped flex circuit assemblies, respectively. Method 1000 may further include positioning 1004 first and second pluralities of conductive contact bumps of the first and second bumped flex circuit assemblies in electrical contact with first and second pluralities of conductive contact pads of the rigid printed circuit assembly, respectively.

In an embodiment, method 1000 of forming an interconnect in may further include sizing 1006 the hard stop assembly to provide a substantially uniform pressure between the first and second pluralities of conductive contact bumps and the first and second pluralities of conductive contact pads, respectively.

What is claimed is:

1. An interconnect assembly, comprising:
a rigid printed circuit assembly having a substrate with first and second sides in opposition to one another, first and second pluralities of conductive contact pads disposed on the first and second sides of the substrate, respectively;
first and second bumped flex circuit assemblies having first and second support plates, respectively, said first and second pluralities of conductive contact bumps extending inwardly toward one another from the first and second support plates, respectively, and the first and second pluralities of conductive contact bumps configured for selective engagement with the first and second pluralities of conductive contact pads; and
a hard stop assembly configured to extend between the first and second support plates and the first and second sides of the substrate, respectively, wherein the hard stop assembly restricts non-uniform motion of the substrate toward the first and second support plates.

2. An interconnect assembly in accordance with claim 1, wherein the hard stop assembly includes first and second pairs of rigid supports extending from the first and second support plates, respectively.

3. An interconnect assembly in accordance with claim 2, wherein the first and second pairs of rigid supports extend a maximum height in a direction perpendicular to a plane in parallel with the first and second support plates, respectively, wherein the maximum height is selected to allow contact and provide a substantially uniform pressure between each of the first and second pluralities of conductive contact bumps and the first and second pluralities of conductive contact pads, respectively.

4. An interconnect assembly in accordance with claim 3, wherein the maximum height of each of the first and second pairs of rigid supports is uniform along an entire length thereof.

5. An interconnect assembly in accordance with claim 4, wherein the maximum height of the first pair of rigid supports is equal to the maximum height of the second pair of rigid supports.

6. An interconnect assembly in accordance with claim 1, wherein the hard stop assembly includes first and second rigid supports extending from first and second sides of the substrate, respectively.

7. An interconnect assembly in accordance with claim 6, wherein the first and second pairs of rigid supports each extend a maximum height from the substrate in a direction perpendicular to a plane in parallel with the substrate, wherein the maximum height is selected to allow contact and provide a substantially uniform pressure between each of the first and second pluralities of conductive contact bumps and the first and second pluralities of conductive contact pads, respectively.

8. An interconnect assembly in accordance with claim 7, wherein the maximum height of each of the first and second pairs of rigid supports is uniform along an entire length thereof.

9. An interconnect assembly in accordance with claim 7, wherein the substrate has a height, and wherein the rigid printed circuit assembly has a height equal to the height of the substrate together with the maximum height of the first pair of rigid supports together with the maximum height of the second pair of rigid supports.

10. An interconnect assembly in accordance with claim 6, wherein the substrate has a stiffness, wherein the hard stop assembly has a stiffness, and wherein the stiffness of the hard stop assembly is greater than the stiffness of the substrate.

11. A method of forming an interconnect, the method comprising:
positioning hard stop assemblies extending from first and second support plates of first and second bumped flex circuit assemblies, respectively, in contact with a rigid printed circuit assembly; and
positioning first and second pluralities of conductive contact bumps of the first and second bumped flex circuit assemblies in electrical contact with first and second pluralities of conductive contact pads of the rigid printed circuit assembly, respectively.

12. A method of forming an interconnect in accordance with claim 11, further comprising sizing the hard stop assembly to provide a substantially uniform pressure between the first and second pluralities of conductive contact bumps and the first and second pluralities of conductive contact pads, respectively.

13. A method of forming an interconnect, the method comprising:
positioning hard stop assemblies extending from a rigid printed circuit assembly in contact with first and second support plates of first and second bumped flex circuit assemblies, respectively; and
positioning first and second pluralities of conductive contact bumps of the first and second bumped flex circuit assemblies in electrical contact with first and second pluralities of conductive contact pads of the rigid printed circuit assembly, respectively.

14. A method of forming an interconnect in accordance with claim 13, further comprising sizing the hard stop assembly to provide a substantially uniform pressure between the first and second pluralities of conductive contact bumps and the first and second pluralities of conductive contact pads, respectively.
